(19) United States
(12) Patent Application Publication
(10) Pub. No.: US 2003/0057464 A1
(43) Pub. Date: Mar. 27, 2003

(54) Ferroelectric memory device and method of fabricating the same

(75) Inventor: Sang-Don Nam, Seoul (KR)

Correspondence Address: MARGER JOHNSON & McCOLLOM, P.C., 1030 S.W. Morrison Street, Portland, OR, 97205, US

(73) Assignee: Samsung Electronics Co., Ltd., Hwasung-City (KR)

(21) Appl. No.: 10/255,841

(22) Filed: Sep. 25, 2002

(30) Foreign Application Priority Data
Sep. 27, 2001 (KR) 2001-59955

(51) Int. Cl. H01L 31/062

(52) U.S. Cl. 257/295

(57) ABSTRACT

A ferroelectric memory device comprises an interlayer insulating layer and an adhesive layer over a semiconductor substrate. A storage node contact plug may extend through the adhesive layer and the interlayer insulating layer to connect a predetermined area of the semiconductor substrate. A ferroelectric capacitor may be connected to the storage node contact plug and on at least a portion of the adhesive layer.

### RELATED APPLICATION

This application claims priority and benefit of Korean Patent Application No. 2001-0059955, filed on Sep. 27, 2001, the contents of which are herein incorporated by reference in their entirety.

### BACKGROUND

The present invention relates to a semiconductor device and its method of fabrication. More specifically, the present invention is directed to a ferroelectric memory device and methods of fabricating a ferroelectric memory device.

Generally, as the level of integration of conventional semiconductor devices increase, an area available for the formation of a capacitor of the semiconductor device may gradually decrease. If the area for the capacitor decreases, then its capacitance may be reduced. In an effort to compensate for reduced capacitance, a thickness of a dielectric layer may be decreased. However, as the thickness of the dielectric layer is reduced, an opportunity for tunneling leakage current may arise, which in turn may compromise the reliability of the capacitor.

Another conventional approach to enhancing the capacitance value without decreasing a thickness of the dielectric layer may comprise roughing the surface topology on an electrode of the capacitor, e.g., a storage node of a storage capacitor. The resulting irregular surface may then increase an effective surface area of the capacitor's electrode.

One conventional capacitor structure comprises a stacked dielectric of, e.g., a nitride layer/an oxide layer or an oxide layer/a nitride layer/an oxide layer. Such a stacked dielectric structure may allow for increased capacitance values.

More recently, ferroelectric materials are being used in the formation of capacitors. The ferroelectric materials may comprise, e.g., materials such as BTO(BaTiO₃), PZT[Pb(Zr, Ti)O₃], BTO(Bi₄TiO3O₁₂), and PLZT[(Pb, La)(Zr, Ti)O₃]. Such materials may retain a remnant polarization despite loss of power to an associated semiconductor device. With such ferroelectric materials, a ferroelectric memory devices may offer an opportunity for data retetion with low standby power consumption.

FIGS. 1 to 3 are simplified cross-sectional views useful for explaining a conventional method of fabricating a ferroelectric memory device.

Referring to FIG. 1, a device isolation layer 102 may be formed on a semiconductor substrate 100 to define an active region. Transistors 104 may be formed on the active region. A first interlayer insulating layer 106 may then be formed on an entire surface of the resultant structure where the transistors 104 are formed. Thereafter, bit line 108 may be formed at a predetermined region on the first interlayer insulating layer. Bit line 108 may penetrate the first interlayer insulating layer to be connected to a source region of transistors 104. Next, second interlayer insulating layer 110 may then be formed on an entire surface of the resultant structure where bit line 108 was formed.

Referring to FIG. 2, the second and first interlayer insulating layers 110 and 106 may then be sequentially patterned to define contact holes and allow formation of storage node contact plugs 112 connected to drain regions of the transistors.

Referring to FIG. 3, an adhesive layer and a lower electrode layer may be sequentially formed on an entire surface of the resultant structure where storage node contact plug 112 is formed. The lower electrode layer and the adhesive layer may be sequentially patterned to form adhesive layer pattern 114 and lower electrode 116 on the second interlayer insulating layer 110. At this time, adhesive layer pattern 114 and lower electrode 116, which are sequentially stacked, are connected to the storage node contact plug 112. Generally, the lower electrode layer may comprise platinum and the adhesive layer one of titanium or tantalum. The adhesive layer may improve the adhesion between the lower electrode layer and the second interlayer insulating layer.

Continuing with further referenced to FIG. 3, dielectric layer 118 may be formed conformal to an entire surface of the resultant structure where lower electrode 116 is formed. The capacitor dielectric layer may be annealed in an oxygen ambient and crystallized. The anneal is to improve characteristics of the ferroelectric dielectric layer, such as its qualities for remnant polarization. Next, an upper electrode 120 may be formed on a surface of the resultant structure where capacitor dielectric layer 118 is formed.

As mentioned above, for the conventional devices, there may exist a region where capacitor dielectric layer 118 directly contacts second interlayer insulating layer 110. Thus, a reaction may occur between silicon oxide of second interlayer insulating layer 110 and the dielectric of capacitor dielectric layer 118. During an anneal of the capacitor dielectric layer, such reaction between the silicon oxide and dielectric may deteriorate a morphology of the dielectric of capacitor dielectric layer 118 and adversely influence polarization characteristics of the ferroelectric. Also, a titanium layer or tantalum of adhesive layer pattern 114 may also be oxidized during the crystallization anneal of the capacitor dielectric layer 118. Such oxidation may increase a resistance between storage node contact plug 112 and capacitor lower electrode 116.

### SUMMARY OF THE INVENTION

Exemplary embodiments of the present invention comprise a ferroelectric memory device, and another embodiment a method of fabricating a ferroelectric memory device, in which an electrical coupling may be preserved between a capacitor lower electrode and a storage node contact plug.

Such exemplary embodiments may also prevent a dielectric layer of a ferroelectric capacitor from reacting with an interlayer insulating layer.

Further exemplary embodiments of the present invention may comprise a ferroelectric memory device with a ferroelectric capacitor of reliable polarization characteristics.

According to an embodiment of the present invention, a ferroelectric memory device comprises an interlayer insulating layer and an adhesive layer covering the entire surface of a semiconductor substrate. A storage node contact plug may penetrate the adhesive layer and the interlayer insulating layer to connect a predetermined region of the semiconductor substrate. A ferroelectric capacitor may be connected to the storage node contact plug and be disposed on the adhesive layer.

In a further embodiment, the ferroelectric capacitor may comprise a lower electrode connected to the storage node, a ferroelectric on the lower electrode and an upper electrode over the ferroelectric. The adhesive layer may be operable to adhere the lower electrode and the interlayer insulating layer.

According to another embodiment of the present invention, a method of forming a ferroelectric device comprises forming an interlayer insulating layer to cover substantially an entire surface of a semiconductor substrate. An adhesive layer may then be formed on the interlayer insulating layer after planarization of the interlayer insulating layer. Next, the adhesive layer and the interlayer insulating layer may both be patterned to define an opening therethrough, i.e., a storage node contact hole to expose a predetermined region of the semiconductor substrate. The storage node contact hole may be filled substantially with conductive material to form a storage node contact plug and in contact with the predetermined region of the semiconductor substrate. A ferroelectric capacitor may then be formed for connection to the storage node contact plug and on an annular region of the adhesive layer beyond the periphery of the contact plug. According to a particular exemplary embodiment, the storage node contact plug may comprise tungsten.

According to a further embodiment, a lower electrode layer, a ferroelectric layer and an upper electrode layer may be sequentially layered on substantially the entire surface of the resultant structure where the storage node contact plug is formed. Thereafter, the upper electrode layer, the ferroelectric layer and the lower electrode layer may be sequentially patterned to define a ferroelectric capacitor connected to the storage node contact plug.

In another exemplary method of forming the ferroelectric capacitor, the lower electrode layer may be formed on substantially an entire surface of the resultant structure where the storage node contact plug may be formed. The lower electrode layer may then be patterned to form a lower electrode connected to the storage node contact plug. After patterning to define the lower electrode, the ferroelectric layer may be formed over and in a conformal contact with exposed surfaces of the lower electrode. An upper electrode may then be conformally deposited to cover the ferroelectric layer.

According to a particular exemplary embodiment of the present invention, the adhesive layer may comprise an insulating material operable to adhere lower electrode and the interlayer insulating layer.

### BRIEF DESCRIPTION OF THE DRAWINGS

FIGS. 1 through 3 are simplified cross-sectional views of a semiconductor substrate during processing, useful to help explain a method of fabricating a conventional ferroelectric memory device.

FIG. 4 is a simplified cross-sectional view showing a ferroelectric memory device in accordance with an embodiment of the present invention.

FIGS. 5 through 8 are simplified cross-sectional views of a semiconductor substrate during processing, useful to help explain a method of fabricating a ferroelectric memory device in accordance with another embodiment of the present invention.

FIG. 9 is a simplified cross-sectional view showing a ferroelectric memory device in accordance a further embodiment of the present invention.

FIGS. 10 and 11 are simplified cross-sectional views of a semiconductor substrate in processing, useful to help explain a method of fabricating a ferroelectric memory device in accordance with yet another embodiment of the present invention.

### DETAILED DESCRIPTION

The present invention will now be described more fully hereinafter with reference to the accompanying drawings, in which exemplary embodiments of the invention may be shown and like numbers are intended to refer to like elements throughout. The invention may, however, be embodied in different forms and should not be construed as limited to the specific embodiments set forth herein. Rather, these embodiments are provided so that this disclosure will be thorough and complete, and will fully convey the scope of the invention to those skilled in the art.

In the drawings, the thickness of layers and regions may be exaggerated for clarity. Additionally, it will also be understood that when a layer is referred to as being “on” another layer or substrate, it can be directly on the other layer or substrate, or intervening layers may also be present.

FIG. 4 is a cross-sectional view showing a ferroelectric memory device in accordance with an embodiment of the present invention.

Referring to FIG. 4, device isolation layer 202 may be disposed at a predetermined region of a semiconductor substrate 200 to define, for example, a boundary of an active region. Transistors 204 are disposed in the active region between the device isolation layers 202. As referenced herein, the transistors may be described using alternative expressions such as, e.g., being formed in, at or on an active region of a semiconductor substrate. Such alternative terms on/in/at may be understood to be used individually for purposes of convenience. In the context of semiconductors devices, such terms when used individually may be understood to collectively reference respective portions of a semiconductor element within and/or on a starting substrate.

For example, with reference to FIG. 4, transistors 204 may comprise source and drain regions 203 that have been doped and/or diffused within portions of semiconductor substrate 200. Additionally, the transistors may also comprise gate structures (e.g. gate oxide, sidewall spacers and conductive material) that have been formed on the upper surface of the semiconductor surface. Thus, the description of a transistor at an active region of a semiconductor substrate may be understood, dependent upon its relative context, to encompass portions within the starting substrate and portions over (yet integrated with) the substrate.

Continuing with the present embodiment, with further reference to FIG. 4, transistors 204 include gate electrodes that may cross the active region. Transistors 204 also include shared source regions 203s and drain regions 203d. Source region 203s and drain regions 203d may be formed in the active region of substrate 206 and may be disposed at both sides of the gate electrode. Bit line 208 may include conductive contacts that pass through a window of first interlayer insulating layer 206 and connect to shared source region 203s of transistors 204. In this embodiment, the first interlayer insulating layer 206 may be described as covering an entire surface of the structure where transistors 204 have been formed. Bit line 208 may cross a predetermined region on the first interlayer insulating layer 206 to electrically connect a peripheral circuit and or other adjacent transistors 204.

Second interlayer insulating layer 210 and adhesive layer 214 may be stacked sequentially over and conformal to exposed surfaces of bit line 208 and first interlayer insulating layer 206. Storage node contact plugs 212 may extend through windows of adhesive-layer 214, second interlayer insulating layer 210 and first interlayer insulating layer 206 to contact respective drain regions 203d of transistors 204. In this particular embodiment, the storage node contact plugs 212 comprise tungsten.

Lower electrodes 216 may be connected to respective storage node contact plugs 212 and may be disposed on annular regions of adhesive layer 214 radially outward from the peripheral outline of the contact plugs. A capacitor dielectric layer 218 may be formed over and conformal to the surface of lower electrodes 216. Upper electrode 220 may similarly be formed to cover capacitor dielectric layer 218. In one embodiment, upper electrode 220 may extend over additional determined regions of semiconductor substrate 200 beyond the outline of lower electrodes 216. In a further embodiment, upper electrodes 220 may comprise widths related to that of lower electrode 216 and lengths that extend along and parallel to gate electrodes of transistors 204. Such extended coverage of the upper electrode may therefore connect capacitors of adjacent cells. For such embodiments, upper electrode 218 may be referenced as a plate electrode.

For certain embodiments, adhesive layer 214 may comprise an insulating layer operable to adhere lower electrode 216 and second interlayer insulating layer 210. For example, adhesive layer 214 may comprise a material selected from the group consisting of Al₂O₃, Ta₂O₅, TiO₂, CeO₂, PZT(Pb[Zr, Ti]O₃) and SBT(SrBi₂Ta₂O₉), or a combination thereof.

As mentioned above, a ferroelectric memory device in accordance an embodiment of the present invention may comprise adhesive layer interposed between portions of the capacitor dielectric layer and the interlayer insulating layer. As a result, according to this embodiment, ferroelectric of the capacitor may be protected from reaction with the interlayer insulating layer.

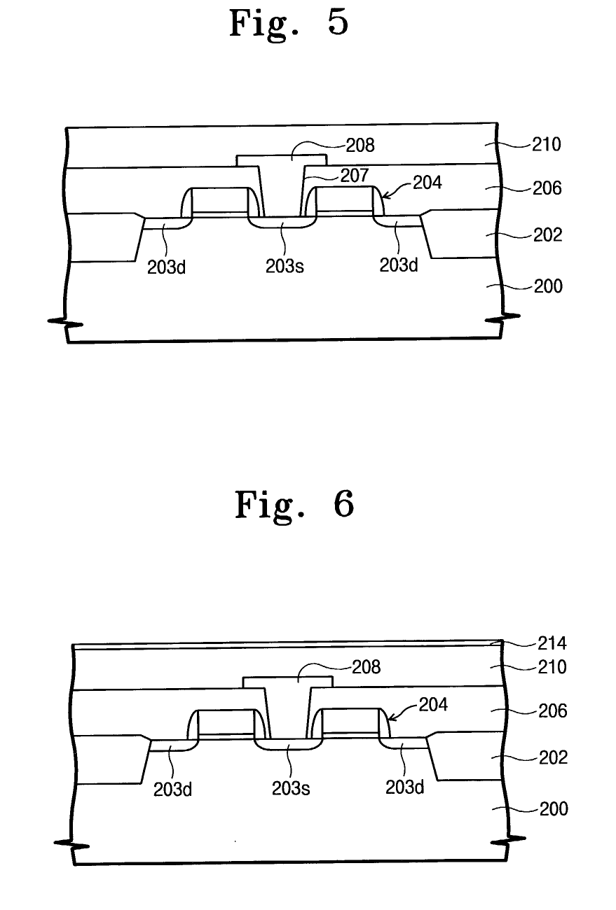

FIGS. 5 through 8 are simplified cross-sectional views of a substrate during processing and will be useful for explaining a method of fabricating a ferroelectric memory device in accordance with an embodiment of the present invention.

Referring to FIG. 5, a device isolation layer 202 may be formed at a predetermined region of a semiconductor substrate to define an active region. A plurality of transistors 204, which include a gate electrode and source/drain impurity regions, may be formed in the active region. The gate electrodes of the transistors may cross the active area, and the source/drain impurity regions may be disposed in the active area and at both sides of the gate electrodes. These impurity regions may be referenced as source region 203s and drain regions 203d.

Next, first interlayer insulating layer 206 may be formed on exposed surfaces of the semiconductor substrate and transistors 204 to cover these regions where the transistors were formed. First interlayer insulating layer 206 may be patterned to form sidewalls 207 and to define a bit line contact hole to expose a portion of source region 203s.

Bit line 208 may then be formed on first interlayer insulating layer 206. Bit line 208 may be formed with a conductive contact that may pass through the bit line contact hole to electrically connect source region 203s.

After forming the bit line with the associated contact coupled to the source region, a second interlayer insulating layer 210 may then be formed on and conformal to exposed surfaces of bit line 208 and layer 206 where the resultant structure with bit line 208 was formed. The first and second interlayer insulating layers 206 and 210, in this exemplary embodiment, may comprise oxide material(s). Additionally, the second interlayer insulating layer 210 may be planarized by an etch back, for example, which may use chemical mechanical polishing (CMP).

Referring to FIG. 6, adhesive layer 214 may be formed on the exposed surface of second interlayer insulating layer 210. In a particular embodiment, the adhesive layer may be formed over the entire surface of the insulating layer. Adhesive layer 214 may be operable to adhere second interlayer insulating layer 210 and an overlying lower electrode layer of a capacitor. Adhesive layer 214, in the present embodiment, may comprise an insulating material operable to preserve ferroelectric characteristics of a capacitor dielectric layer. For example, adhesive layer 214 may comprise at least one material selected from the group consisting of Al₂O₃, Ta₂O₅, TiO₂, CeO₂, PZT(Pb[Zr, Ti]O₃) and SBT(SrBi₂Ta₂O₉).

It may again be noted that some conventional devices have the capacitor dielectric in direct contact with an interlayer insulating layer, which may allow silicon of the interlayer insulating layer to diffuse into the capacitor dielectric layer. Such diffusion, in turn, may compromise the integrity of the capacitor dielectric layer. In contrast, the present exemplary embodiment of the invention, comprises an adhesive layer interposed between the capacitor dielectric and the interlayer insulating layer, which may prevent silicon of interlayer insulating layer from migrating into the capacitor dielectric layer.

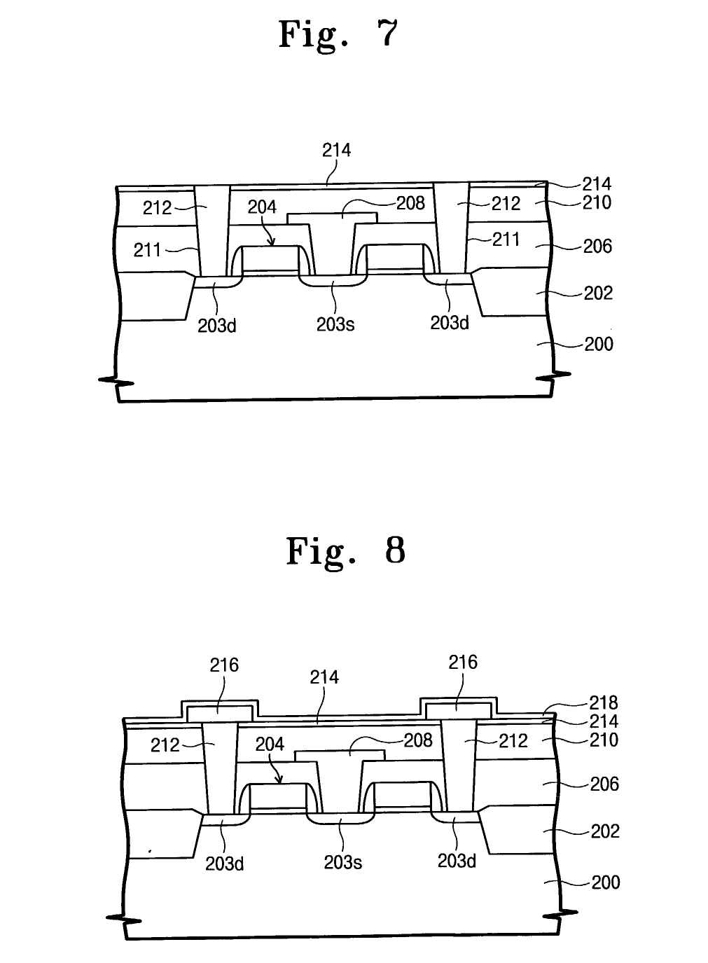

Referring to FIG. 7, adhesive layer 214, second interlayer insulating layer 210 and first interlayer insulating layer 206 may be sequentially patterned to form sidewalls 211 and to define a storage node contact holes for exposing portions of drain regions 203d. Conductive material may then be disposed into the storage node contact holes and over the surface of adhesive layer 214. The conductive material may comprise, in this embodiment, a material that may maintain its conductivity during subsequent processes. For example, the conductive layer may comprise tungsten. Next, an etch-back (such as chemical mechanical planarization) of the conductive layer may be used to define storage node contact plugs 212 in the storage node contact holes.

Referring to FIG. 8 material for a lower electrode may be formed on an entire surface of the resultant structure where the storage node contact plug 212 was formed. The lower electrode layer may comprise platinum. In further embodiments, it may comprise at least one metal selected from the platinum group consisting of platinum, ruthenium, iridium, rhodium, osmium, palladium and their associated oxides. This group may be understood to comprise elements neighboring platinum within the periodic chart.

Continuing with further reference to FIG. 8, the layer of material for the lower electrode layer may be patterned to form lower electrodes 216 on adhesive layer 214 and in contact with storage node contact plugs 212. In this embodiment, lower electrode 216 also resides on an annular surface region of the adhesive layer radially outward from the peripheral outline of the contact hole.

After defining the lower electrode, ferroelectric layer 218 may be formed on an entire surface of the resultant structure where lower electrodes 216 have been formed. The ferroelectric may be formed conformal to exposed surfaces of lower electrodes 216. Ferroelectric layer 218 may be alternatively referenced herein as a capacitor dielectric layer, and may comprise a material selected from the group consisting of SrTi₃, BaTiO₃, Pb(Zr, Ti)O₃, SrBi₂Ta₂O₉, (Pb, La)(Zr, Ti)O₃, Bi₄Ti₃O1₂ and Pb(Zr, Ti)O₃. Ferroelectric layer 218 may be formed by sputtering or chemical vapor deposition (CVD). In another embodiment, the formation of ferroelectric layer 218, may comprise coating a ferroelectric source in the sol-gel state on the entire surface of the resultant structure where lower electrode 216 has been formed. After layering the ferroelectric material for capacitor dielectric layer 218, it may be annealed in an oxidizing ambient for improving a polarization characteristic of the capacitor dielectric layer 218. As a result, the crystallized ferroelectric layer may hold a superior polarization characteristic.

According to one embodiment of the present invention, a height of lower electrode 216 may be adjusted to enhance an effective area of the capacitor dielectric layer. This may be helpful when the realization of the capacitor needs to be confined within a limited area of the substrate.

Furthermore, in accordance with this embodiment, an upper electrode layer may be formed on the exposed surface of capacitor dielectric layer 218. The upper electrode layer may be referenced as an upper electrode of the capacitor, i.e., a plate electrode. Like the lower electrode layer, the upper electrode layer, in this embodiment, may comprise a metal or a metal oxide of the platinum group.

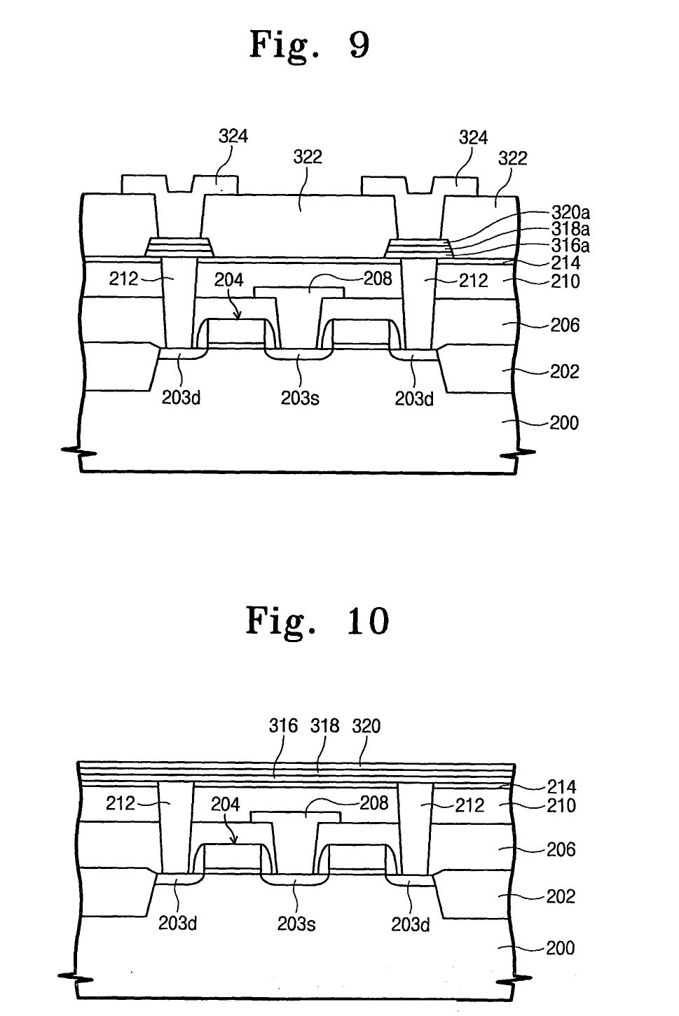

FIG. 9 is a simplified cross-sectional view showing a ferroelectric memory device in accordance with another embodiment of the present invention.

Similar to the embodiment previously described with reference to FIG. 5, device isolation layer 202 may be disposed at a predetermined region of a semiconductor substrate to define an active region. Thereafter, first interlayer insulating layer 206, second interlayer insulating layer 210 and adhesive layer 214 may be sequentially stacked on transistors predisposed in the active region.

Storage node contact plugs 212 may pass through adhesive layer 214, second interlayer insulating layer 210 and first interlayer insulating layer 206 collectively to contact respective drain regions 203d of transistors 204. Bit line 208 may be disposed between the first and second interlayer insulating layers 206 and 210. Additionally, bit line 208 may include contact members that pass through first interlayer insulating layer 206 to connect source region 203s of transistors 204.

A ferroelectric capacitor may be connected to the storage node contact plugs 212 and may also be disposed on annular portions of adhesive layer 214 radically beyond the peripheral outline of the plug holes. In this exemplary embodiment, the ferroelectric capacitor comprises a stacked structure of lower electrode 316a, dielectric layer 318a and upper electrode 320a. Dielectric layer 318a and upper electrode 320a may be sequentially stacked on lower electrode 316a. A third insulating layer 322 may then be formed to cover the ferroelectric capacitor. Plate electrode 324 may pass through an opening in the third interlayer insulating layer 322 to be connected to upper electrode 320a.

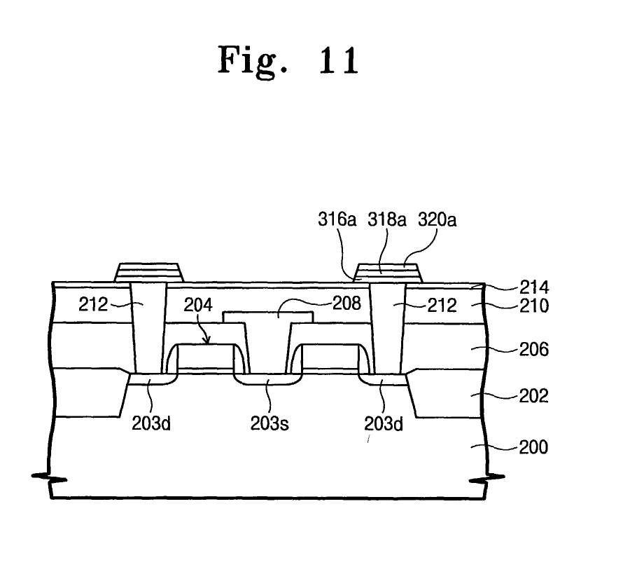

FIGS. 10 and 11 are simplified cross-sectional views useful for explaining a method of fabricating a ferroelectric memory device in accordance with another embodiment of the present invention.

Referring to FIG. 10, an adhesive layer and storage node contact plugs 212 may be formed similarly to the exemplary embodiments described above. After forming the adhesive layer and storage node contact plugs, lower electrode layer 316, ferroelectric layer 318 and upper electrode layer 320 may be sequentially formed on an entire surface of the resultant structure where the storage node contact plugs 212 have been formed. Lower electrode layer 316, ferroelectric layer and upper electrode layer 320 may comprise materials similar to those of the respective elements of the previously descried embodiments, e.g., as previously described with reference to FIG. 4. Additionally, the ferroelectric layer 318 may be formed similarly to the ferroelectric layer of the previously described first embodiments. That is, ferroelectric layer 318 may be formed by one of sputtering or chemical vapor deposition (CVD), or sol-gel processes. Again, the ferroelectric layer may then be annealed in an oxidizing ambient.

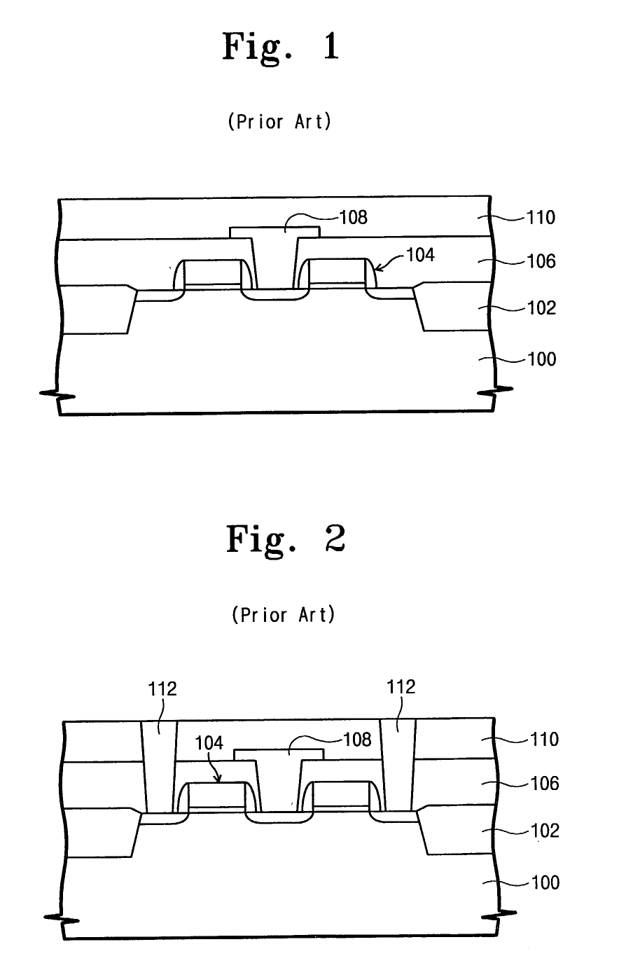

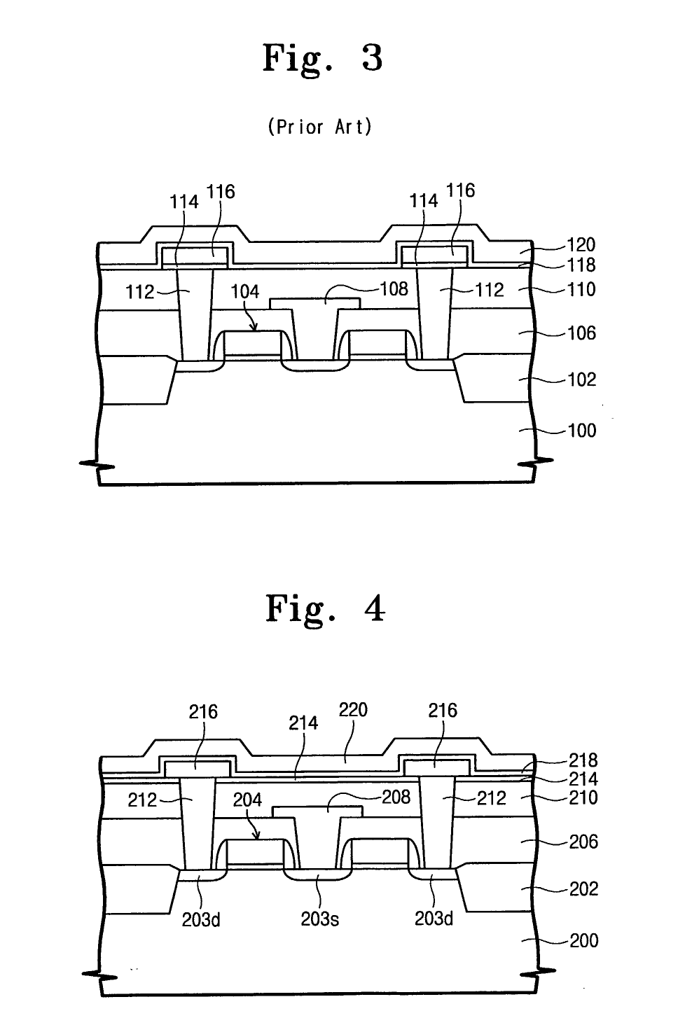

Referring to FIG. 1, upper electrode layer 320, ferroelectric layer 318 and lower electrode layer 316 may then be sequentially patterned to form a ferroelectric capacitor on adhesive layer 214 and connected to storage node contact plugs 212. As shown in FIG. 11, the resulting ferroelectric capacitor comprises patterned lower electrode 316a, capacitor dielectric layer 318a and upper electrode 320a. The patterned capacitor dielectric layer 318a and upper electrode 320a may be described as a sequentially stacked on lower electrode 316a. Lower electrode 316a may be connected to an upper surface of its respective storage node contact plug 212. Additionally, such lower electrode 316a may be described with a flange portion on an annular region of the adhesive layer radially beyond the peripheral outline of the plug contact hole.

Continuing a description of this exemplary embodiment, although not shown explicitly in the drawings, an insulating layer may be formed on an entire surface of the resultant structure where the ferroelectric capacitor is formed. The insulating layer may then be patterned to form a plate electrode hole and to expose a portion of upper electrode 320a. A plate electrode (such as, e.g., 324 of FIG. 9) may then be formed to fill the plate electrode hole and electrically connect selected ferroelectric capacitors. In such embodiment, a ferroelectric memory device, e.g., such as that of FIG. 9 may be fabricated.

As mentioned above, according to exemplary embodiments of the present invention, it is possible to fabricate ferroelectric memory devices with ferroelectric capacitors capable of maintaining their polarization characteristics.

In addition, a resistance between the capacitor and its storage node contact plug may be kept low to enable polarization of the ferroelectric capacitor with a low operating voltage.

In the drawings and specification, there have been disclosed typical embodiments of this invention and, although specific terms are employed, they may be used in a generic and descriptive sense only and not for purposes of limitation. Additionally, it will be apparent to those skilled in this art that the particular embodiments illustrated or described herein are exemplary and that various changes and modifications may be made thereto as become apparent upon reading the present disclosure. Accordingly, such changes and modifications shall be deemed to fall within the scope of the appended claims.

What is claimed is:

1. A ferroelectric memory device, comprising:
an interlayer insulating layer and an adhesive layer on surface of a semiconductor substrate;
a storage node contact plug extending through the adhesive layer and the interlayer insulating layer and connected to a predetermined region of the semiconductor substrate;
a lower electrode connected to the storage node plug and disposed on at least a portion of the adhesive layer;
dielectric covering the lower electrode; and
an upper electrode covering the dielectric.

2. The ferroelectric memory device of claim 1, the adhesive layer comprising at least one material selected from the group consisting of Al₂O₃, Ta₂O₅, TiO₂, CeO₂, PZT(Pb[Zr, Ti]O₃) and SBT(SrBi₂Ta₂O₉).

3. The ferroelectric memory device of claim 1, the capacitor dielectric layer conformal to sidewalls and a top surface of the lower electrode.

4. The ferroelectric memory device of claim 1, the storage node contact plug comprising tungsten.

5. A ferroelectric memory device, comprising:
at least one transistor at an active region of a semiconductor substrate;
a first interlayer insulating layer over the transistor;
a bit line on the first interlayer insulating layer and electrically connected to a source region of the transistor;
a second interlayer insulating layer and an adhesive layer over the bit line;
the adhesive layer, the second interlayer insulating layer and the first interlayer insulating layer together comprising sidewalls to define an opening therethrough for accessing a drain region of the transistor;
a storage node contact plus disposed within the opening and contacting with the drain region; and
a ferroelectric layer disposed on the adhesive layer and in contact with the storage node contact plug.

6. The ferroelectric memory device of claim 5, the adhesive layer comprising of at least one material selected from the group consisting of Al₂O₃, Ta₂O₅, TiO₂, CeO₂, PZT(Pb[Zr, Ti]O₃) and SBT(SrBi₂Ta₂O₉).

7. The ferroelectric memory device of claim 5, wherein the storage node contact plug comprises tungsten.

8. The ferroelectric memory device of claim 5, in which the ferroelectric capacitor comprises:
a lower electrode connected to the storage node contact plug;
a capacitor dielectric layer on the lower electrode; and
an upper electrode on the capacitor dielectric layer.

9. The ferroelectric memory device of claim 8, the capacitor dielectric layer in conformal contact with a top surface and sidewalls of the lower electrode.

10. The ferroelectric memory device of claim 8, the lower electrode, the capacitor dielectric layer and the upper electrode sequentially stacked over the storage node contact plug.

11. A method of fabricating a ferroelectric memory device, comprising:
forming a layer of insulating material over a surface of a semiconductor substrate;
forming an adhesive layer over a surface of the layer of insulating material;
patterning the adhesive layer and the layer of insulating material to form a hole therethrough and exposing a predetermined area of the semiconductor substrate;
disposing conductive material in the hole and in contact with the predetermined area of the semiconductor substrate; and
forming a ferroelectric capacitor in contact with the storage node contact plug and on the adhesive layer.

12. The method of claim 11, further comprising planarizing the layer of insulating material.

13. The method of claim 11, in which the forming the conductive material comprises filling the hole with tungsten to form a storage node contact plug.

14. The method of claim 11, in which the forming the adhesive layer comprises layering at least one material selected from the group consisting of Al₂O₃, Ta₂O₅, TiO₂, CeO₂, PZT(Pb[Zr, Ti]O₃) and SBT(SrBi₂Ta₂O₉).

15. The method of claim 11, in which the forming the ferroelectric capacitor comprises:
forming a lower electrode layer on the adhesive layer and in contact with the conductive material;
patterning the lower electrode layer to form a lower electrode connected to the conductive material, the patterning to define the lower electrode with at least a portion thereof to extend over an annular region of the adhesive layer beyond a periphery of the hole;
forming a capacitor dielectric layer covering and conformal to the exposed surface of the lower electrode; and
forming an upper electrode layer on the capacitor dielectric layer.

16. The method of claim 15, in which the forming the capacitor dielectric layer employs a process selected from the group consisting of sputtering, chemical vapor deposition (CVD), and sol-gel processes.

17. The method of claim 11, in which the forming the ferroelectric capacitor comprises:
sequentially forming a lower electrode layer, a capacitor dielectric layer and an upper electrode on exposed surfaces of the semiconductor substrate and the conductive material in the hole; and
sequentially patterning the upper electrode layer, the capacitor dielectric layer and the lower electrode layer to form a ferroelectric capacitor connected to the conductive material.

18. The method of claim 17, further comprising:
forming a third interlayer insulating layer over the semiconductor substrate and on exposed surfaces of ferroelectric capacitor;
patterning the third interlayer insulating layer to define an opening therethrough and expose a portion of the upper electrode of the ferroelectric capacitor; and
forming a plate electrode connected to the exposed portion of the upper electrode.

19. The method of claim 17, in which the capacitor dielectric layer is formed by at least one of sputtering, chemical vapor deposition (CVD) or sol-gel processes.

20. A method of forming a ferroelectric memory device, comprising:
forming a first interlayer insulating layer covering an entire surface of a semiconductor substrate with transistors;
forming a bit line on the first interlayer insulating layer and in contact with a source region of the transistors;
forming a second interlayer insulating layer over the first interlayer insulating layer and the bit line;
planarizing the second interlayer insulating layer;
forming an adhesive layer on the planarized second interlayer insulating layer;
sequentially patterning the adhesive layer, the second interlayer insulating layer and the first interlayer insulating layer and forming a contact hole therethrough and exposing a drain region of a transistor;
filling the contact hole with a conductive material and forming a contact plug; and
forming a ferroelectric capacitor connected to the contact plug and on the second interlayer insulating layer.

21. The method of claim 20, in which the filling fills the contact hole with tungsten.

22. The method of claim 20, in which the forming the adhesive layer comprises forming a layer of material selected from the group consisting of Al₂O₃, Ta₂O₅, TiO₂, CeO₂, PZT(Pb[Zr, Ti]O₃) and SBT(SrBi₂Ta₂O₉).

23. The method of claim 20, in which the forming a ferroelectric capacitor comprises forming an electrode in contact with the contact plug and over an annular portion of the planarized second interlayer insulating layer, the annular portion radially outward from a periphery of the contact hole.
